(19) United States
(12) Patent Application Publication
(10) Pub. No.: US 2025/0322999 A1
(43) Pub. Date: Oct. 16, 2025

(54) ROTATION INPUT DEVICE

(71) Applicant: ALPS ALPINE CO., LTD., Tokyo (JP)

(72) Inventors: Katsuya SAIJO, Miyagi (JP); Mariko ITO, Miyagi (JP)

(21) Appl. No.: 19/081,347

(22) Filed: Mar. 17, 2025

(30) Foreign Application Priority Data
Apr. 11, 2024 (JP) 2024-063923

(51) Int. Cl. H01H 19/20; G06F 3/02; H01H 19/14; H03K 17/975

(52) U.S. Cl. CPC H01H 19/20; H01H 19/14; H03K 17/975; G06F 3/0202; H03K 2217/94073

(57) ABSTRACT

A rotation input device includes a fixing body having an attachment surface, a rotary body supported by the fixing body in such a manner that the rotary body is rotatable around an axial direction orthogonal to the attachment surface, a rotating electrode attached to the rotary body, a plurality of fixed electrodes attached to the fixing body at respective positions along a circumferential direction around the axial direction, a code plate attached to the rotary body and having a code portion, and a plurality of contact spring portions integrally extending from the respective fixed electrodes and being in elastic contact with the code portion. The contact spring portion extends from an end portion of the fixed electrode in the circumferential direction toward the code portion via a folded portion.

### CROSS-REFERENCE TO RELATED APPLICATIONS

Priority is claimed to Japanese Patent Application No. 2024-063923, filed Apr. 11, 2024, the entire content of which is incorporated herein by reference.

### BACKGROUND

### 1. Technical Field

The present invention relates to a rotation input device.

### 2. Description of Related Art

International Publication No. WO 2019/098055 (hereinafter “Patent Document 1”) discloses a technique for detecting rotation of a rotary part in an input device based on a change in an electrical connection state between a holding electrode part and a rotary electrode part that is caused by a rotation of the rotary electrode part that rotates in accordance with rotation of the rotary part.

### SUMMARY

According to an embodiment of the disclosure, a rotation input device includes: a fixing body having an attachment surface, a rotary body supported by the fixing body in such a manner that the rotary body is rotatable around an axial direction orthogonal to the attachment surface, a rotating electrode attached to the rotary body, a plurality of fixed electrodes attached to the fixing body at respective positions along a circumferential direction around the axial direction, a code plate attached to the rotary body, arranged at a position spaced apart from the plurality of fixed electrodes in the axial direction, electrically connected to the rotating electrode at all times, and having a code portion in which a portion with a conductor and a portion without a conductor alternately appear along the circumferential direction, and a plurality of contact spring portions that are in elastic contact with the code portion and in which a state of an electrical connection with the code plate switches in accordance with a rotation angle of the rotary body, the contact spring portions integrally extending from the respective fixed electrodes. The contact spring portion extends from an end portion of the fixed electrode in the circumferential direction toward the code portion via a folded portion.

### BRIEF DESCRIPTION OF THE DRAWINGS

FIG. 1 is an external perspective view of a rotation input device according to an embodiment;

FIG. 2 is an external perspective view of the rotation input device (separated from a rotating operation body) according to the embodiment;

FIG. 3 is an exploded perspective view of the rotation input device according to the embodiment as viewed from above;

FIG. 4 is an exploded perspective view of the rotation input device according to the embodiment as viewed from below;

FIG. 5 is a cross-sectional view of the rotation input device according to the embodiment;

FIG. 6 is an external perspective view of a fixing body included in the rotation input device according to the embodiment, as viewed from above;

FIG. 7 is a cross-sectional perspective view of the rotation input device according to the embodiment, which is cut along a vertical plane and viewed from below; and

FIG. 8 is an external perspective view of a fixed electrode of the rotation input device according to the embodiment.

### DETAILED DESCRIPTION

In the technique of Patent Document 1, however, a brush that comes into contact with the rotary electrode part is provided at an intermediate position of the holding electrode part. Therefore, in the technique of Patent Document 1, when the spring length of the brush is increased, the area of the holding electrode part is reduced, and it is difficult to stably detect a change in capacitance, and it is difficult to stably detect the presence or position of the holding electrode part. Furthermore, in the technique of Patent Document 1, when the area of the holding electrode part is increased, the spring length of the brush cannot be increased.

According to the rotation input device according to an embodiment of the present disclosure, an increase in the spring length of a contact spring part and an increase in the area of a fixed electrode can be both achieved.

Hereinafter, an embodiment will be described with reference to the drawings. In the following description, for convenience, the Z-axis direction in the drawings is referred to as the “vertical direction”, the Y-axis direction in the drawings is referred to as the “horizontal direction”, and the X-axis direction in the drawings is referred to as the “front-rear direction”. Herein, the positive Z-axis direction is an upward direction, the positive Y-axis direction is a rightward direction, and the positive X-axis direction is a forward direction.

### Outline of Rotation Input Device 100

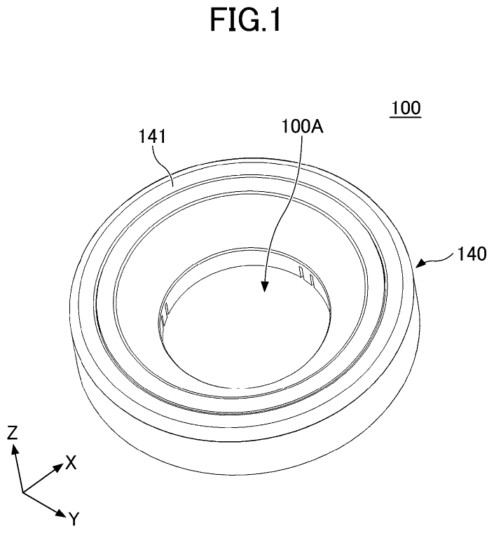

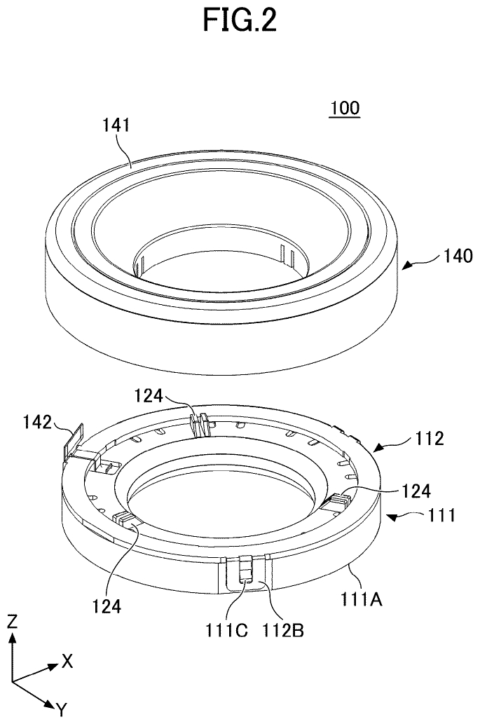

FIG. 1 is an external perspective view of a rotation input device 100 according to an embodiment. FIG. 2 is an external perspective view of the rotation input device 100 (separated from a rotating operation body 140) according to the embodiment.

As illustrated in FIGS. 1 and 2, the rotation input device 100 has a substantially cylindrical shape that is thin in the vertical direction (Z-axis direction) as an outer shape. In the center of the rotation input device 100 as viewed from above, a circular opening 100A is formed and penetrates the rotation input device 100 in the vertical direction (Z-axis direction).

The bottom surface of a fixing body 111 serves as an attachment surface 111A, and the rotation input device 100 can be fixed to the operation surface of a touch-panel display by attaching the attachment surface 111A to the operation surface of the touch-panel display with a double-sided adhesive tape or the like.

The annular rotating operation body 140 of the rotation input device 100 is supported by the fixing body 111 so as to be rotatable about the vertical direction (Z-axis direction). This allows the rotating operation body 140 to be operable with an operator's finger in the rotation input device 100.

A metal-made, annular rotating electrode 141 is provided along the outer periphery of the rotating operation body 140 at the upper end portion of the rotating operation body 140. The rotating electrode 141 is connected to a code plate 130 by a connecting terminal 142 having electrical conductivity. Thus, in the rotation input device 100, the operator's finger operating the rotating operation body 140 and the detection electrode of the touch-panel display can be capacitively coupled via the rotating electrode 141, the code plate 130, and the fixed electrode 150, and the detection electrode of the touch-panel display can detect a rotation operation of the rotating operation body 140 by the operator's finger.

As described above, since the rotation input device 100 according to the embodiment detects a rotation operation of the rotating operation body 140 through the detection electrode of the touch-panel display, the configuration related to the detection of a rotation operation can be simplified, and in particular, a wiring member (for example, a flexible substrate or the like) for connection to external devices can be omitted in the configuration.

Since the rotation input device 100 according to the embodiment has the opening 100A penetrating the rotation input device 100 in the vertical direction, when the rotation input device 100 is installed on the operation surface of the touch-panel display, the region that overlaps the opening 100A in the touch-panel display can be effectively used as a display region.

### Configuration of Rotation Input Device 100

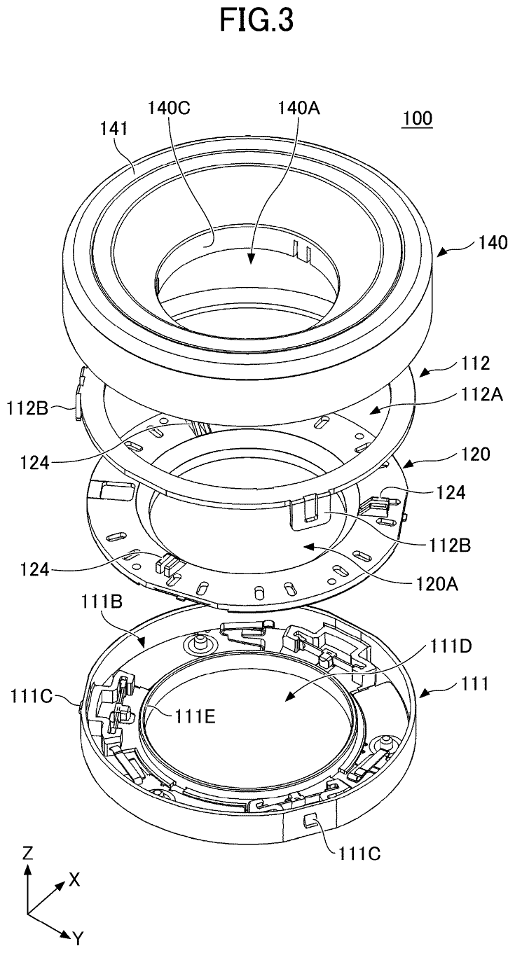

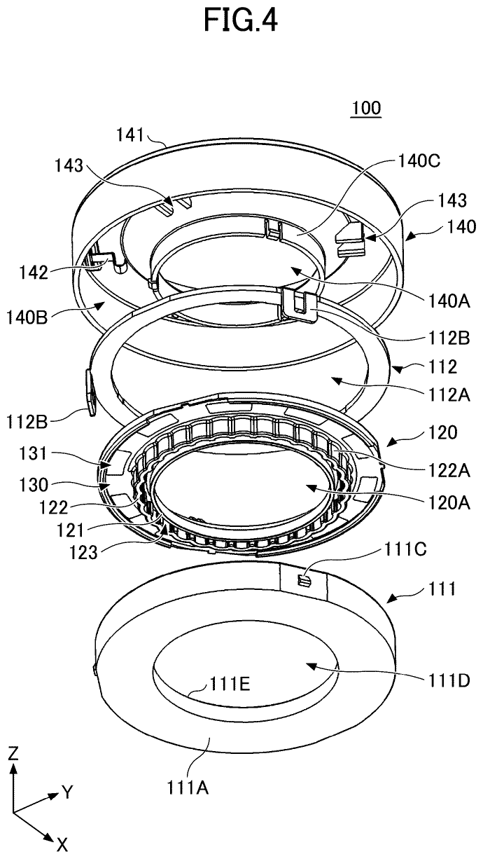

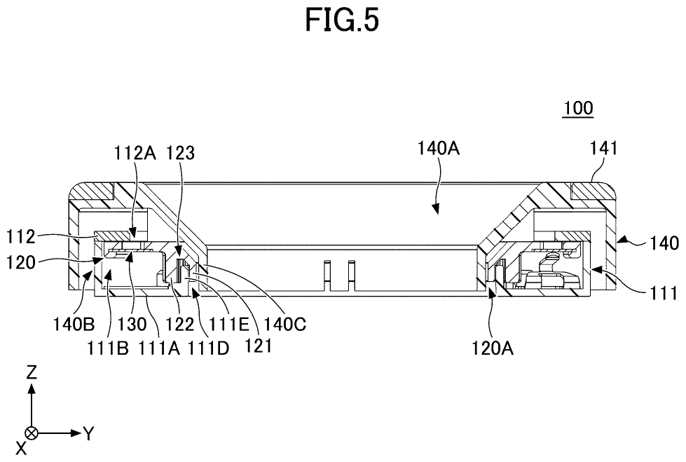

FIG. 3 is an exploded perspective view of the rotation input device 100 according to the embodiment as viewed from above. FIG. 4 is an exploded perspective view of the rotation input device 100 according to the embodiment as viewed from below. FIG. 5 is a cross-sectional view of the rotation input device 100 according to the embodiment.

As illustrated in FIGS. 3 to 5, the rotation input device 100 includes the fixing body 111, a cover 112, the rotating operation body 140, and a rotating disc 120. The rotating operation body 140 and the rotating disc 120 constitute a rotary body.

The fixing body 111 is a container-shaped member having an annular shape when viewed from above and whose upper portion is open. In the central portion of the fixing body 111 when viewed from above, a circular central opening 111D that penetrates the fixing body 111 in the vertical direction (Z-axis direction) is formed. The fixing body 111 is arranged in an inner space 140B of the rotating operation body 140, which also has an annular shape. At this time, an inner cylinder portion 140C of the rotating operation body 140 is inserted into the central opening 111D of the fixing body 111. Thus, the fixing body 111 supports the rotating operation body 140 rotatably about the vertical direction (Z-axis direction).

The fixing body 111 is fixed to the operation surface of the touch-panel display by attaching the bottom surface of the fixing body 111 serving as the attachment surface 111A to the operation surface of the touch-panel display with a double-sided adhesive tape or the like.

The fixing body 111 has the annular inner space 111B whose upper portion is open. The rotating disc 120 is accommodated in the inner space 111B. The upper opening of the inner space 111B is closed by the cover 112. The fixing body 111 is formed using, for example, a relatively hard insulating material (for example, a hard resin or the like).

A plurality of claw portions 111C protruding outward are formed on the outer peripheral surface of the fixing body 111. When the cover 112 is attached to the fixing body 111, the claw portions 111C are fitted into respective openings of a plurality of the hooks 112B of the cover 112 (see FIG. 2), and thus the hooks 112B are hooked, and the cover 112 can be fixed to the fixing body 111.

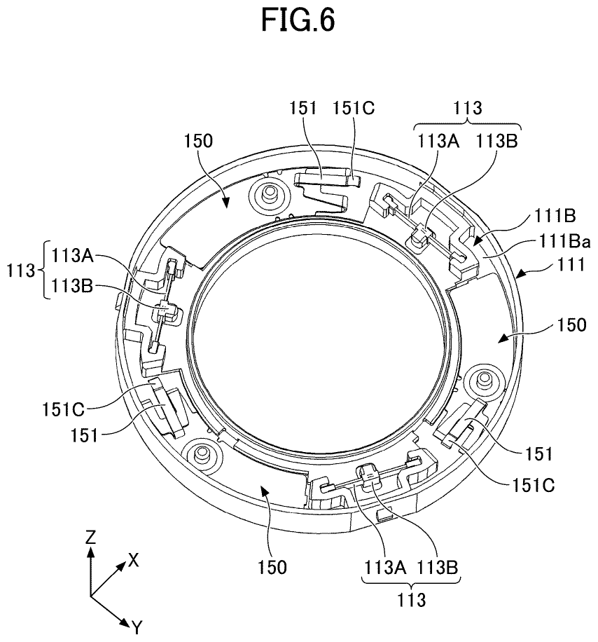

The inner configuration of the inner space 111B of the fixing body 111 will be described later with reference to FIG. 6.

The cover 112 is a horizontal plate-like member made of resin and having an annular shape when viewed from above. The cover 112 is stationarily attached to the fixing body 111 to close the upper opening of the inner space 111B of the fixing body 111. The cover 112 is formed by, for example, injection molding. In a top view, a circular opening 112A through which the inner cylinder portion 140C of the rotating operation body 140 is inserted is formed at the center of the cover 112.

The plurality of hooks 112B hanging downward are provided on the outer peripheral edge of the cover 112. Each hook 112B has a rectangular opening, and the claw portion 111C provided on a side surface of the fixing body 111 is fitted into the opening (see FIG. 1). Thus, the hooks 112B are respectively hooked on the claw portions 111C, and the cover 112 can be fixed to the fixing body 111.

The rotating operation body 140 is a member made of resin that receives a rotation operation by an operator. The rotating operation body 140 has a substantially cylindrical outer shape that is thin in the vertical direction (Z-axis direction). In other words, the rotating operation body 140 has an annular shape when viewed from above. In the center of the rotation operation body 140 as viewed from above, a circular opening 140A is formed and penetrates the rotation operation body 140 in the vertical direction (Z-axis direction). The rotating operation body 140 has the annular inner space 140B whose lower portion is open. The fixing body 111 is arranged in the inner space 140B.

The rotating operation body 140 has the substantially cylindrical inner cylinder portion 140C on the rotation center side of the inner space 140B. The inner cylinder portion 140C of the rotating operation body 140 is inserted into the central opening 111D of the fixing body 111 arranged in the inner space 140B and the opening 120A of the rotating disc 120 rotatably supported by the fixing body 111. Thus, the rotating operation body 140 is supported by the fixing body 111 so as to be rotatable about the vertical direction (Z-axis direction), and the rotating operation body 140 can be rotated by the operator's finger.

The rotating disc 120 is a horizontal disc-shaped member made of resin. The rotating disc 120 is rotatably arranged in the inner space 111B of the fixing body 111. In the center of the rotation plate 120 as viewed from above, a circular opening 120A is formed and penetrates the rotation plate 120 in the vertical direction (Z-axis direction). The inner cylinder portion 140C of the rotating operation body 140 is inserted into the opening 120A.

The rotating disc 120 includes a first inner wall portion 121 and a second inner wall portion 122, which respectively have an annular shape and protrude downward along the inner peripheral edge portion of the rotating disc 120. The first inner wall portion 121 is provided on the inner side in the radial direction, and the second inner wall portion 122 is provided on the outer side in the radial direction. The inner side of the first inner wall portion 121 in the radial direction is, in other words, the opening 120A through which the inner cylinder portion 140C of the rotating operation body 140 is inserted. A plurality of arc-shaped cam lobes 122A for giving a click feeling to a rotation operation of the rotating operation body 140 are provided in a circumferential direction on the outer peripheral surface of the second inner wall portion 122.

In the rotating disc 120, a gap between the first inner wall portion 121 and the second inner wall portion 122 is an annular engagement groove 123. The rotating disc 120 is rotatably supported by the fixing body 111 by inserting an annular inner wall portion 111E of the fixing body 111 into the engagement groove 123 from below.

In the rotating disc 120, a plurality of engagement projections 124 provided to protrude upward from the upper surface portion are respectively engaged with a plurality of engagement grooves 143 provided on the ceiling surface of the inner space 140B of the rotating operation body 140. Thus, when the rotating operation body 140 is rotated, the rotating disc 120 rotates integrally with the rotating operation body 140 about the vertical direction (Z-axis direction).

The annular code plate 130 made of a metal plate is provided on the lower surface of the rotating disc 120. The code plate 130 is provided with a plurality of openings 131 arranged intermittently along a circumferential direction. Thus, the code plate 130 has a code portion in which a portion having a conductor (i.e., a portion in which the opening 131 is not provided) and a portion having no conductor (i.e., a portion in which one of the openings 131 is provided) alternately appear along a circumferential direction.

### Inner Configuration of Inner Space 111B of Fixing Body 111

FIG. 6 is an external perspective view of the fixing body 111 included in the rotation input device 100 according to the embodiment, as viewed from above.

As illustrated in FIG. 6, three pressing members 113 are arranged at equal intervals (i.e., at intervals of 120°) at different positions along a circumferential direction on the bottom surface portion 111Ba of the inner space 111B of the fixing body 111.

The pressing member 113 includes a metal-made plate spring 113A extending linearly in a direction of a tangent line of a circumference formed by the inner space 111B, and a resin-made projection 113B provided at the center of the plate spring 113A. The pressing member 113 is provided to face the radially inner side so that the tip end portion of the projection 113B is pressed against the outer peripheral surface of the second inner wall portion 122 of the rotating disc 120 by a resilient force from the plate spring 113A. In the pressing member 113, both end portions of the plate spring 113A are held by the fixing body 111 in such a manner that the projection 113B can follow the plurality of cam lobes 122A and move in the radial direction when the plate spring 113A is elastically deformed.

As illustrated in FIG. 6, three fixed electrodes 150 are arranged at equal intervals (i.e., at intervals of 120°) at different positions along a circumferential direction on the bottom surface portion 111Ba of the inner space 111B of the fixing body 111. Each of the three fixed electrodes 150 is provided at a position not overlapping the pressing member 113 in a circumferential direction, in other words, provided between two adjacent pressing members 113.

Each of the fixed electrodes 150 is a member made of a metal plate. The fixed electrodes 150 are provided so as to extend in a circumferential direction along the bottom surface portion 111Ba of the inner space 111B of the fixing body 111. Specifically, each of the fixed electrodes 150 has one end at the end portion on the counterclockwise side and the other end at the end portion on the clockwise side when viewed from above, and extends in a curved shape from one end to the other end along the bottom surface portion 111Ba of the inner space 111B of the fixing body 111.

The fixed electrodes 150 are fixed to the bottom surface portion 111Ba of the inner space 111B of the fixing body 111 by any fixing means (for example, rivets or the like).

Each of the fixed electrodes 150 has a contact spring portion 151 at the other end (the end portion on the clockwise side). The contact spring portion 151 integrally extends from the fixed electrode 150. The contact spring portion 151 extends in such a manner that the height position of the contact portion 151C provided at the tip portion of the contact spring portion 151 is the highest. The contact spring portion 151 is in elastic contact with, at the contact portion 151C, the lower surface of the code plate 130 provided to face the upper side of the fixed electrode 150. Thus, the state of an electrical connection between the contact spring portion 151 and the code plate 130 switches in accordance with a rotation angle of the rotating operation body 140 and the rotating disc 120.

Each fixed electrode 150 can be capacitively coupled to the operator's finger via the contact spring portion 151, the code plate 130, the connecting terminal 142, and the rotating electrode 141. Since each fixed electrode 150 is provided at a position close to the operation surface of the touch-panel display, when the fixed electrode 150 is capacitively coupled to the operator's finger, the capacitance can be detected by the detection electrode of the touch-panel display.

### Actions of Pressing Members 113 and Contact Spring Portions 151

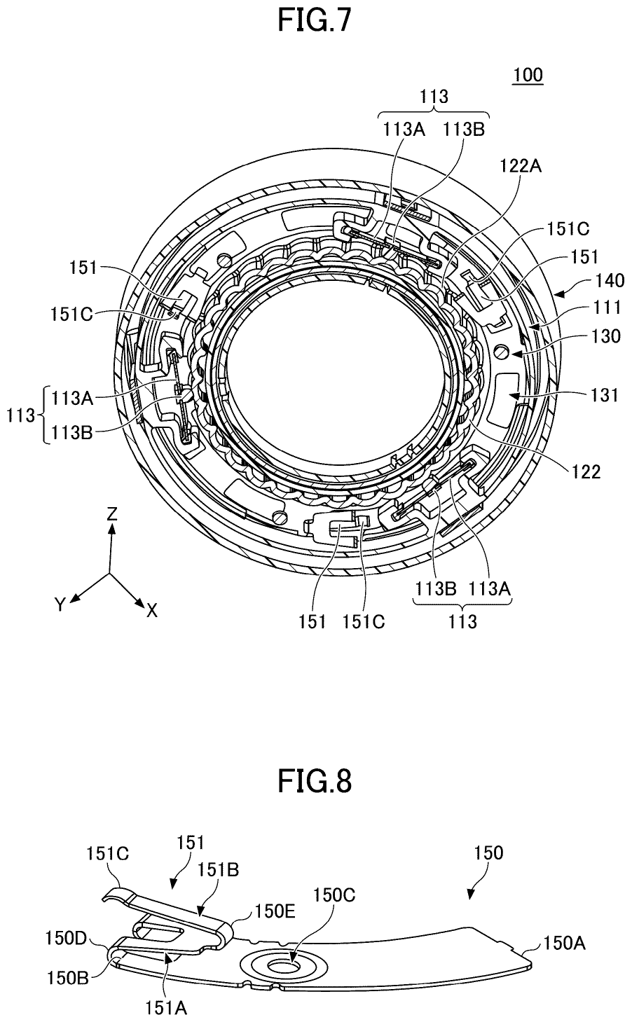

FIG. 7 is a cross-sectional perspective view of the rotation input device 100 according to the embodiment, which is cut along a vertical plane and viewed from below.

As illustrated in FIG. 7, the tip of the projection 113B of each of the three pressing members 113 provided on the fixing body 111 is in contact with the outer circumferential surface of the second inner wall portion 122 of the rotating disc 120, and the tip of the projection 113B slides on the outer circumferential surface of the second inner wall portion 122 of the rotating disc 120 in accordance with rotation of the rotating operation body 140 and the rotating disc 120. At this time, the projection 113B moves in the radial direction along the plurality of cam lobes 122A provided on the outer peripheral surface of the second inner wall portion 122 while elastically deforming the plate spring 113A, and when the projection 113B is fitted between two adjacent cam lobes 122A, the rotation of the rotating operation body 140 and the rotating disc 120 is immediately stopped. Thus, each of the three pressing members 113 can provide a click feeling at every predetermined rotation angle (as an example, every 12° in the present embodiment) in response to the rotation operation of the rotating operation body 140 by the operator.

As illustrated in FIG. 7, the respective contact spring portions 151 of the three fixed electrodes 150 provided on the fixing body 111 are respectively in elastic contact with the contact portions 151C each provided at the tip portions of the contact spring portions 151 to the lower surface of the code plate 130 provided with the plurality of openings 131 intermittently in a circumferential direction, and the contact portions 151C slide on the lower surface of the code plate 130 in accordance with rotation of the rotating operation body 140, the rotating disc 120, and the code plate 130. Thus, the electrical connection between each contact spring portion 151 and the code plate 130 is alternately switched between a state of being electrically connected to the code plate 130 (i.e., a state of being in elastic contact inside the opening 131) and a state of not being electrically connected to the code plate 130 (i.e., a state of being in elastic contact outside of the opening 131) in accordance with a rotation angle of the rotating operation body 140 and the rotating disc 120.

The fixed electrode 150 is electrically connected to the rotating electrode 141 via the code plate 130 and the connecting terminal 142 by the contact spring portion 151 being electrically connected to the code plate 130, and can be capacitively coupled to the operator's finger in contact with the rotating electrode 141. As a result, the fixed electrode 150 can cause the detection electrode provided at a position facing the fixed electrode 150 in the touch-panel display to detect a capacitance of the operator's finger via the fixed electrode 150. Therefore, the touch-panel display can detect a rotation direction and a rotation angle of a rotation operation of the rotation operation body 140 by detecting a change in the electrostatic capacitance of the three fixed electrodes 150, which is caused by the rotation operation.

In particular, in the present embodiment, the plurality of openings 131 are formed in the code plate 130 in such a manner that at least one fixed electrode 150 is electrically connected to the code plate 130 for all rotation angles at every predetermined rotation angle (as an example, every 12° in the present embodiment). Thus, the rotation input device 100 according to the embodiment can detect a capacitance of the operator's finger by the detection electrode of the touch-panel display via at least one fixed electrode 150 at all rotation angles. In other words, in the rotation input device 100 according to the embodiment, a rotation angle at which a capacitance of the operator's finger cannot be detected is not generated, and it is therefore possible to suppress erroneous detection of a rotation operation of the rotating operation body 140.

### Configuration of Fixed Electrodes 150

FIG. 8 is an external perspective view of the fixed electrode 150 included in the rotation input device 100 according to the embodiment. The three fixed electrodes 150 of the rotation input device 100 are the same as the fixed electrodes 150 illustrated in FIG. 8.

As illustrated in FIG. 8, the fixed electrode 150 is formed using a relatively thin metal plate, the fixed electrode 150 extends in a curved shape from the end portion on the counterclockwise side (hereinafter “one end 150A”) to the other end portion on the clockwise side (hereinafter “the other end 150B”) along the bottom surface portion 111Ba of the inner space 111B of the fixing body 111, as viewed from above.

In the example illustrated in FIG. 8, the fixed electrode 150 is formed with a circular through hole 150C at an intermediate position in the extending direction, and can be easily and reliably fixed to the bottom surface portion 111Ba of the inner space 111B of the fixing body 111 with a rivet or the like penetrating the through hole 150C.

As illustrated in FIG. 8, the fixed electrode 150 has a contact spring portion 151 (so-called brush) on the other end 150B (the end portion on the clockwise side). The contact spring portion 151 integrally extends from the fixed electrode 150, and the contact portion 151C which is brought into elastic contact with the lower surface of the code plate 130 is provided at the tip portion of the contact spring portion 151.

As illustrated in FIG. 8, in the fixed electrode 150 of the present embodiment, the contact spring portion 151 extends upward (i.e., toward the lower surface of the code plate 130) from the other end 150B via a first folded portion 150D.

Thus, the fixed electrode 150 of the present embodiment does not have the contact spring portion 151 in the area between the one end 150A and the other end 150B, and therefore the area size of the fixed electrode 150 can be maximized. Therefore, a change in the capacitance can be stably captured through the touch-panel display, and the presence or position of the fixed electrode 150 can be stably detected.

As a result, in the fixed electrode 150 of the present embodiment, the contact spring portion 151 can be provided to overlap the upper side of the fixed electrode 150, and thus, the spring length of the contact spring portion 151 can be made relatively long while the area size of the fixed electrode 150 is maximized.

Therefore, according to the rotation input device 100 of the embodiment, it is possible to increase the spring length of the contact spring portion 151 and to increase the area size of the fixed electrode 150 at the same time.

In particular, as illustrated in FIG. 8, the fixed electrode 150 of the present embodiment includes a first extending portion 151A in which the contact spring portion 151 extends from one end of the first extending portion 151A at the other end 150B of the fixed electrode 150 via the first folded portion 150D to the other end of the first extending portion 151A in the direction opposite to the extending direction of the fixed electrode 150 (i.e., the counterclockwise direction), and a second extending portion 151B in which the contact spring portion 151 extends from one end of the second extending portion 151B at the one end of the first extending portion 151A via a second folded portion 150E to the other end of the second extending portion 151B in the direction opposite to the first extending portion 151A (i.e., the clockwise direction).

Thus, in the fixed electrode 150 of the present embodiment, the spring length of the contact spring portion 151 can be increased, and the height position of the contact portion 151C in the vertical direction can also be increased. Therefore, according to the fixed electrodes 150 of the present embodiment, even in the case where the fixed electrodes 150 are relatively distant from the code plate 130 in the vertical direction, the contacts 151C can be reliably brought into elastic contact with the lower surface of the code plate 130, and therefore, poor electrical connection between the code plate 130 and the code plate 130 can be suppressed.

In the rotation input device 100 according to the embodiment, as a preferred example, as illustrated in FIGS. 6 and 7, the plurality of fixed electrodes 150 are three fixed electrodes 150, and are arranged at intervals of 120° along a circumferential direction with the vertical direction (Z-axis direction) as the center.

Thus, the rotation input device 100 according to the embodiment can separate the fixed electrodes 150 from each other to the maximum extent, and therefore, stable detection can be performed using the plurality of fixed electrodes 150.

However, the present invention is not limited thereto, and the plurality of fixed electrodes 150 may be constituted by two, four, or more fixed electrodes 150.

As a modification of the fixed electrodes 150, the fixed electrode 150 may be configured in such a manner that the contact spring portion 151 has the first extending portion 151A extending from one end at the other end 150B of the fixed electrode 150 via the first folded portion 150D to the other end in a direction opposite to the extending direction of the fixed electrode 150 (i.e., the counterclockwise direction), and the contact portion 151C extends from the other end of the first extending portion 151A. In other words, the fixed electrode 150 may be configured in such a manner that the second extending portion 151B is not provided.

Even in this case, the fixed electrode 150 of the present embodiment does not have the contact spring portion 151 between the one end 150A and the other end 150B, and therefore the area size of the fixed electrode 150 can be maximized. Therefore, a change in the capacitance can be stably captured through the touch-panel display, and the presence or position of the fixed electrode 150 can be stably detected.

Even in this case, in the fixed electrode 150 of the present embodiment, the contact spring portion 151 can be provided to overlap the upper side of the fixed electrode 150, and thus, the spring length of the contact spring portion 151 can be made relatively long while the area size of the fixed electrode 150 is maximized.

Although the embodiment of the present invention has been described in detail, the present invention is not limited to these embodiments, and various modifications or changes can be made within the scope of the gist of the present invention described in the claims.

What is claimed is:

1. A rotation input device comprising:
a fixing body having an attachment surface;
a rotary body supported by the fixing body in such a manner that the rotary body is rotatable around an axial direction orthogonal to the attachment surface;
a rotating electrode attached to the rotary body;
a plurality of fixed electrodes attached to the fixing body at respective positions along a circumferential direction around the axial direction;
a code plate attached to the rotary body, arranged at a position spaced apart from the plurality of fixed electrodes in the axial direction, electrically connected to the rotating electrode at all times, and having a code portion in which a portion with a conductor and a portion without a conductor alternately appear along the circumferential direction; and
a plurality of contact spring portions that are in elastic contact with the code portion and in which a state of an electrical connection with the code plate switches in accordance with a rotation angle of the rotary body, the contact spring portions integrally extending from the respective fixed electrodes, wherein
the contact spring portion extends from an end portion of the fixed electrode in the circumferential direction toward the code portion via a folded portion.

2. The rotation input device according to claim 1, wherein
the fixed electrode extends from one end to an other end along the circumferential direction, and
the contact spring portion includes
a first extending portion extending from one end at the other end of the fixed electrode via a first folded portion to an other end in a direction opposite to an extending direction of the fixed electrode,
a second extending portion extending from one end at the other end of the first extending portion via a second folded portion to an other end in a direction opposite to the extending direction of the first extending portion, and
a contact portion extending from the other end of the second extending portion.

3. The power rotation input device according to claim 1, wherein
the plurality of fixed electrodes are three fixed electrodes, and are arranged at intervals of 120° along a circumferential direction around the axial direction.
